(19) United States
(12) Patent Application Publication
(10) Pub. No.: US 2025/0293666 A1
(43) Pub. Date: Sep. 18, 2025

(54) MULTILAYER INTERDIGITAL TRANSDUCER ELECTRODE INCLUDING A MOLYBDENUM LAYER AND AN ALUMINUM LAYER

(71) Applicant: Skyworks Solutions, Inc., Irvine, CA (US)

(72) Inventors: Rei Goto, Osaka-Shi (JP); Shoji Okamoto, Hirakata-Shi (JP); Tatsuya Fujii, Nagaokakyo-Shi (JP)

(21) Appl. No.: 19/071,234

(22) Filed: Mar. 5, 2025

Related U.S. Application Data
(60) Provisional application No. 63/565,198, filed on Mar. 14, 2024.
(60) Provisional application No. 63/565,203, filed on Mar. 14, 2024.

(51) Int. Cl. H03H 9/145; H03H 9/02; H03H 9/25

(52) U.S. Cl. CPC H03H 9/14541; H03H 9/02559; H03H 9/25

(57) ABSTRACT

A multi-layer piezoelectric substrate surface acoustic wave device is disclosed. The surface acoustic wave device is configured to generate a wave having a wavelength of L. The surface acoustic wave device can include a substrate, a piezoelectric layer over the substrate, and a multi-layer interdigital transducer electrode in electrical communication with the piezoelectric layer. The multi-layer interdigital transducer electrode includes a first layer having molybdenum and a second layer having aluminum. A first thickness of the first layer is in a range between 0.02L and 0.05L. A second thickness of the second layer is in a range between 1 and 2.5 times the first thickness.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/565,198, filed Mar. 14, 2024, titled “MULTILAYER PIEZOELECTRIC SUBSTRATE SURFACE ACOUSTIC WAVE DEVICE WITH MULTILAYER INTERDIGITAL TRANSDUCER ELECTRODE,” and U.S. Provisional Patent Application No. 63/565,203, filed Mar. 14, 2024, titled “MULTILAYER INTERDIGITAL TRANSDUCER ELECTRODE INCLUDING A MOLYBDENUM LAYER AND AN ALUMINUM LAYER,” are hereby incorporated by reference under 37 CFR 1.57 in their entirety.

### BACKGROUND

### Field

Embodiments of this disclosure relate to multilayer piezoelectric substrate surface acoustic wave (MPS SAW) devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a multi-layer piezoelectric substrate surface acoustic wave device configured to generate a wave having a wavelength of L, the surface acoustic wave device including: a substrate; a piezoelectric layer over the substrate; and a multi-layer interdigital transducer electrode in electrical communication with the piezoelectric layer, the multi-layer interdigital transducer electrode including a first layer and a second layer over the first layer, a first mass density of the first layer being greater than a second mass density of the second layer, a first thickness of the first layer being in a range between 0.02 L and 0.05 L multiplied by a normalized value of the first mass density normalized by a mass density of molybdenum, a second thickness of the second layer being in a range between 1 and 2.5 times the first thickness, the second thickness being 100 nanometers or greater and 0.08 L or less.

In some embodiments, the techniques described herein relate to a surface acoustic wave device wherein the first layer includes molybdenum, tungsten, or platinum.

In some embodiments, the techniques described herein relate to a surface acoustic wave device wherein the second layer includes aluminum.

In some embodiments, the techniques described herein relate to a surface acoustic wave device wherein the piezoelectric layer includes lithium tantalate or lithium niobate.

In some embodiments, the techniques described herein relate to a surface acoustic wave device wherein the wavelength is in a range between 3 micrometers to 6 micrometers.

In some embodiments, the techniques described herein relate to a surface acoustic wave device wherein the second thickness is in a range between 1.8 and 2.2 times the first thickness.

In some embodiments, the techniques described herein relate to a surface acoustic wave device further including a functional layer between the substrate and the piezoelectric layer.

In some embodiments, the techniques described herein relate to a surface acoustic wave device wherein the second layer has a sidewall that extends between a bottom side and a top side of the second layer, an angle between the sidewall and the bottom side is in a range between 45 degrees and 95 degrees.

In some embodiments, the techniques described herein relate to a surface acoustic wave device wherein a first width of the first layer is greater than a second width of the second layer.

In some embodiments, the techniques described herein relate to a surface acoustic wave device wherein the sidewall of the second layer is offset from a sidewall of the first layer by an offset length in a range between 0.01 L and 0.08 L.

In some embodiments, the techniques described herein relate to a surface acoustic wave device wherein the first layer is at least partially positioned in the piezoelectric layer.

In some aspects, the techniques described herein relate to a multi-layer piezoelectric substrate surface acoustic wave device configured to generate a wave having a wavelength of L, the surface acoustic wave device including: a substrate; a piezoelectric layer over the substrate; and a multi-layer interdigital transducer electrode in electrical communication with the piezoelectric layer, the multi-layer interdigital transducer electrode including a first layer and a second layer over the first layer, a first mass density of the first layer being greater than a second mass density of the second layer, the first layer having a normalized mass loading exchange rate normalized by a mass loading exchange rate of molybdenum, a first thickness of the first layer being in a range between 0.02 L and 0.05 L multiplied by the normalized mass loading exchange rate, a second thickness of the second layer being in a range between 1 and 2.5 times the first thickness, the second thickness being 100 nanometers or greater and 0.08 L or less.

In some embodiments, the techniques described herein relate to a surface acoustic wave device wherein the first layer includes molybdenum, tungsten, or platinum.

In some embodiments, the techniques described herein relate to a surface acoustic wave device wherein the second layer includes aluminum.

In some embodiments, the techniques described herein relate to a surface acoustic wave device wherein the piezoelectric layer includes lithium tantalate or lithium niobate.

In some embodiments, the techniques described herein relate to a surface acoustic wave device wherein the wavelength is in a range between 3 micrometers to 6 micrometers.

In some embodiments, the techniques described herein relate to a surface acoustic wave device wherein the second thickness is in a range between 1.8 and 2.2 times the first thickness.

In some embodiments, the techniques described herein relate to a surface acoustic wave device wherein the second layer has a sidewall that extends between a bottom side and a top side of the second layer, an angle between the sidewall and the bottom side is in a range between 45 degrees and 95 degrees.

In some embodiments, the techniques described herein relate to a surface acoustic wave device the sidewall of the second layer is offset from a sidewall of the first layer by an offset length in a range between 0.01 L and 0.08 L.

In some aspects, the techniques described herein relate to an acoustic wave filter including: a multi-layer piezoelectric substrate surface acoustic wave device configured to filter a wave having a wavelength of L, the surface acoustic wave device including a multi-layer interdigital transducer electrode in electrical communication with a piezoelectric layer, the multi-layer interdigital transducer electrode including a first layer and a second layer over the first layer, a first mass density of the first layer being greater than a second mass density of the second layer, a first thickness of the first layer being in a range between 0.02 L and 0.05 L multiplied by a normalized value of the first mass density normalized by a mass density of molybdenum, a second thickness of the second layer being in a range between 1 and 2.5 times the first thickness, the second thickness being 100 nanometers or greater and 0.08 L or less; and a plurality of other acoustic wave devices, the multi-layer piezoelectric substrate surface acoustic wave device and the plurality of other acoustic wave devices together arranged to filter a radio frequency signal.

In some aspects, the techniques described herein relate to a multi-layer piezoelectric substrate surface acoustic wave device configured to generate a wave having a wavelength of L, the surface acoustic wave device including: a substrate; a piezoelectric layer over the substrate; and a multi-layer interdigital transducer electrode in electrical communication with the piezoelectric layer, the multi-layer interdigital transducer electrode including a first layer having molybdenum and a second layer having aluminum, a first thickness of the first layer being in a range between 0.02 L and 0.05 L, a second thickness of the second layer being in a range between 1 and 2.5 times the first thickness.

In some embodiments, the techniques described herein relate to a surface acoustic wave device wherein the second thickness is 100 nanometers or greater.

In some embodiments, the techniques described herein relate to a surface acoustic wave device wherein the second thickness is 0.08 L or less.

In some embodiments, the techniques described herein relate to a surface acoustic wave device wherein the piezoelectric layer includes lithium tantalate or lithium niobate.

In some embodiments, the techniques described herein relate to a surface acoustic wave device wherein the wavelength is in a range between 3 micrometers to 6 micrometers.

In some embodiments, the techniques described herein relate to a surface acoustic wave device wherein the second thickness of the second layer is in a range between 1.8 times and 2.2 times the first thickness.

In some embodiments, the techniques described herein relate to a surface acoustic wave device further including a functional layer between the substrate and the piezoelectric layer.

In some embodiments, the techniques described herein relate to a surface acoustic wave device wherein the second layer has a sidewall that extends between a bottom side and a top side of the second layer, an angle between the sidewall and the bottom side is in a range between 45 degrees and 95 degrees.

In some embodiments, the techniques described herein relate to a surface acoustic wave device wherein a first width of the first layer is greater than a second width of the second layer.

In some embodiments, the techniques described herein relate to a surface acoustic wave device wherein the sidewall of the second layer is offset from a sidewall of the first layer by an offset length in a range between 0.01 L and 0.08 L.

In some embodiments, the techniques described herein relate to a surface acoustic wave device wherein the first layer is at least partially positioned in the piezoelectric layer.

In some aspects, the techniques described herein relate to a multi-layer piezoelectric substrate surface acoustic wave device configured to generate a wave having a wavelength of L, the surface acoustic wave device including: a substrate; a piezoelectric layer over the substrate; and a multi-layer interdigital transducer electrode in electrical communication with the piezoelectric layer, the multi-layer interdigital transducer electrode including a first layer and a second layer over the first layer, the second layer having aluminum, a first thickness of the first layer being in a range between 0.02 L and 0.05 L, a second thickness of the second layer being in a range between 1 and 2.5 times the first thickness, the second thickness being 100 nanometers or greater and 0.08 L or less.

In some embodiments, the techniques described herein relate to a surface acoustic wave device wherein the piezoelectric layer includes lithium tantalate or lithium niobate.

In some embodiments, the techniques described herein relate to a surface acoustic wave device wherein the wavelength is in a range between 3 micrometers to 6 micrometers.

In some embodiments, the techniques described herein relate to a surface acoustic wave device wherein the second thickness of the second layer is in a range between 1.8 times and 2.2 times the first thickness.

In some embodiments, the techniques described herein relate to a surface acoustic wave device further including a functional layer between the substrate and the piezoelectric layer.

In some embodiments, the techniques described herein relate to a surface acoustic wave device wherein the second layer has a sidewall that extends between a bottom side and a top side of the second layer, an angle between the sidewall and the bottom side is in a range between 45 degrees and 95 degrees.

In some embodiments, the techniques described herein relate to a surface acoustic wave device wherein a first width of the first layer is greater than a second width of the second layer.

In some embodiments, the techniques described herein relate to a surface acoustic wave device wherein the sidewall of the second layer is offset from a sidewall of the first layer by an offset length in a range between 0.01 L and 0.08 L.

In some aspects, the techniques described herein relate to an acoustic wave filter including: a multi-layer piezoelectric substrate surface acoustic wave device configured to filter a wave having a wavelength of L, the surface acoustic wave device including a multi-layer interdigital transducer electrode formed with a piezoelectric layer, the multi-layer interdigital transducer electrode including a first layer having molybdenum and a second layer having aluminum, a first thickness of the first layer being in a range between 0.02 L and 0.05 L, a second thickness of the second layer being in a range between 1 and 2.5 times the first thickness; and a plurality of other acoustic wave devices, the multi-layer piezoelectric substrate surface acoustic wave device and the plurality of other acoustic wave devices together arranged to filter a radio frequency signal.

The present disclosure relates to U.S. patent application Ser. No. ______ [Attorney Docket SKYWRKS.1532A1], titled “MULTILAYER PIEZOELECTRIC SUBSTRATE SURFACE ACOUSTIC WAVE DEVICE WITH MULTILAYER INTERDIGITAL TRANSDUCER ELECTRODE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a surface acoustic wave (SAW) device according to an embodiment.

FIG. 2A shows a simulated strain distribution in a portion of a SAW device.

FIG. 2B shows a simulated strain distribution in a portion of the SAW device shown in FIG. 1 according to an embodiment.

FIG. 2C shows a simulated strain distribution in a portion of the SAW device shown in FIG. 1 according to another embodiment.

FIG. 2D is a graph of four simulated results showing maximum stain in the x-axis and instant destruction power values in decibel milliwatts (dBm) in the y-axis.

FIG. 3A is a graph of simulated results showing an aluminum layer thickness in the x-axis and the strain in the y-axis.

FIG. 3B is a graph of simulated results showing an aluminum layer thickness in the x-axis and the instant destruction power values in decibel milliwatts (dBm) in the y-axis.

FIGS. 4A-4D are graphs showing quality factor (Q) and coupling coefficient (k2) of the SAW device of FIG. 1 at different interdigital transducer electrode layer thicknesses.

FIGS. 5A and 5B show simulated admittance and Q of the SAW device of FIG. 1 with a 100 nm molybdenum layer and a 200 nm aluminum layer and the SAW device of FIG. 2A.

FIGS. 6A-6C are schematic cross-sectional side views of the SAW device of FIG. 1 showing simulated strain distributions therein with different sidewall angles.

FIG. 6D is a graph showing simulated maximum strain values at different sidewall angles.

FIG. 7 is a graph showing simulated maximum strain values at different sidewall angles and offset lengths.

FIG. 8A is a schematic diagram of a transmit filter that includes a surface acoustic wave resonator according to an embodiment.

FIG. 8B is a schematic diagram of a receive filter that includes a surface acoustic wave resonator according to an embodiment.

FIG. 9 is a schematic diagram of a radio frequency module that includes a surface acoustic wave resonator according to an embodiment.

FIG. 10 is a schematic diagram of a radio frequency module that includes filters with surface acoustic wave resonators according to an embodiment.

FIG. 11 is a schematic block diagram of a module that includes an antenna switch and duplexers that include a surface acoustic wave resonator according to an embodiment.

FIG. 12A is a schematic block diagram of a module that includes a power amplifier, a radio frequency switch, and duplexers that include a surface acoustic wave resonator according to an embodiment.

FIG. 12B is a schematic block diagram of a module that includes filters, a radio frequency switch, and a low noise amplifier according to an embodiment.

FIG. 13A is a schematic block diagram of a wireless communication device that includes a filter with a surface acoustic wave resonator in accordance with one or more embodiments.

FIG. 13B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate (MPS) SAW device.

A multilayer piezoelectric substrate (MPS) surface acoustic wave (SAW) device can include a support substrate, a piezoelectric layer over the support substrate, and an interdigital transducer (IDT) electrode in electrical communication with the piezoelectric layer. A multilayer IDT electrode structure that includes two or more metal layers can be implemented in a SAW device to reduce the size of the SAW device. The thermal dissipation ability of the MPS SAW device is generally greater than other types of SAW devices, such as a temperature compensated (TC) SAW device that includes a temperature compensation layer over the IDT electrode.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, high power durability can be a significant aspect for enabling a reliable SAW device. Various properties, such as materials and dimensions, of the components in a SAW device can affect the quality value, (Q), the coupling coefficient (k2), the frequency ability, and/or the power durability. A precise selection of, for example, the materials and dimensions of the multilayer IDT electrode can be significant for providing a multilayer piezoelectric substrate (MPS) surface acoustic wave (SAW) device with a relatively high quality factor (Q), a relatively large effective electromechanical coupling coefficient (k2), a relatively high frequency ability, and a relatively high power durability.

Various embodiments disclosed herein relate to multi-layer piezoelectric substrate surface acoustic wave (MPS SAW) devices with a multi-layer interdigital transducer electrode that are configured to provide a relatively high quality factor (Q), a relatively large effective electromechanical coupling coefficient (k2), a relatively high frequency ability, and a relatively high power durability. The MPS SAW device can be configured to generate a shear horizontal mode surface acoustic wave in which the main mode of the acoustic wave generated by the surface acoustic wave device is shear horizontal mode.

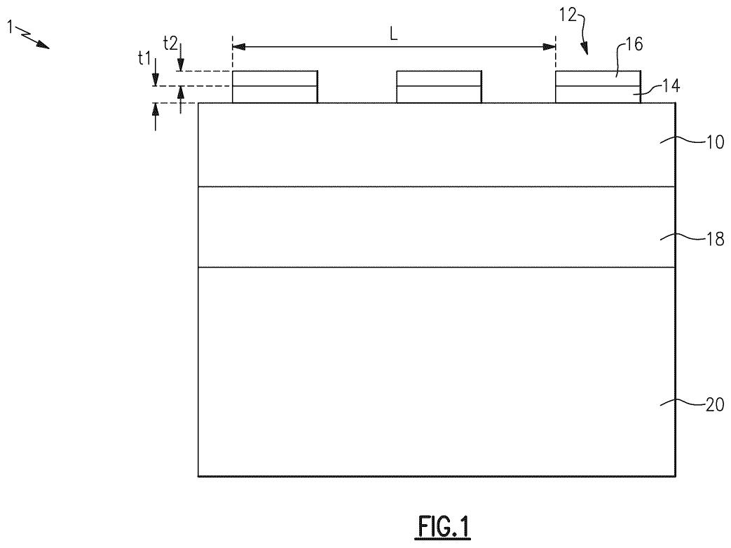

FIG. 1 is a schematic cross-sectional side view of a surface acoustic wave (SAW) device 1 according to an embodiment. The illustrated SAW device 1 can include a piezoelectric layer 10, an interdigital electrode transducer (IDT) electrode 12 that includes a first layer 14 and a second layer 16 in electrical communication with (e.g., disposed on, over, in, buried in, embedded in, or at least partially positioned in) the piezoelectric layer 10, a functional layer 18 below the piezoelectric layer 10, and a support substrate 20 below the functional layer 18. The IDT electrode 12 is a multilayer IDT electrode (e.g., an IDT electrode with two or more metal layers). The SAW device 1 is an example of a multilayer piezoelectric substrate (MPS) SAW device. The SAW device 1 generates a surface acoustic wave having a wavelength λ or L. In some embodiments, the SAW device 1 may include an overcoat layer (not shown) that has a thickness of 0.1 L or less.

The piezoelectric layer 10 can include any suitable piezoelectric layer, such as a lithium based piezoelectric layer. In some embodiments, the piezoelectric layer 10 can be a lithium tantalate (LT) layer. For example, the piezoelectric layer 10 can be an LT layer having a cut angle of 20° (20° Y-cut X-propagation LT) or a cut angle of 60° (60° Y-cut X-propagation LT). For example, the piezoelectric layer 10 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 10. For example, the piezoelectric layer 10 can be an LN layer having a cut angle of about 118° (118° Y-cut X-propagation LN) or more or a cut angle of about 132° (132Y-cut X-propagation LN) or less. For example, the piezoelectric layer 10 can be 125±20° Y-cut LN, 125±15° Y-cut LN, 125±10° Y-cut LN, or 125±5° Y-cut LN. A thickness of the piezoelectric layer 10 can be selected based on a wavelength λ or L of a surface acoustic wave generated by the SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 10 can be sufficiently thick to avoid significant frequency variation. For example, the thickness of the piezoelectric layer 10 can be in a range of 0.1 L to 0.5, 0.1 L to 0.3 L, or 0.1 L to 0.2 L. Selecting the thickness of the piezoelectric layer 10 from these ranges can be critical in avoiding significant frequency variation and providing sufficient temperature coefficient of frequency for the SAW device 1. In some embodiments, the piezoelectric layer 10 can include lithium tantalate (LT) and lithium niobate (LN).

The illustrated IDT electrode 12 includes a first layer 14 and a second layer 16. One of the first layer 14 and the second layer 16 can be more electrically conductive than the other, and the other one can be more durable (e.g., resistive to metal fatigue). In some embodiments, the first layer 14 or the second layer 16 can have a higher mass density and/or higher Young's modulus than the other.

The first layer 14 of the IDT electrode 12 can be referred to as a lower electrode layer. The first layer 14 of the IDT electrode 12 can be disposed between the second layer 16 of the IDT electrode 12 and the piezoelectric layer 10. As illustrated, the first layer 14 of the IDT electrode 12 can have a first side in physical contact with the piezoelectric layer 10 and a second side in physical contact with the second layer 16 of the IDT electrode 12. The second layer 16 of the IDT electrode 12 can be referred to as an upper electrode layer. The second layer 16 of the IDT electrode 12 can be disposed over the first layer 14 of the IDT electrode 12. As illustrated, the second layer 16 of the IDT electrode 12 can have a first side in physical contact with the first layer 14 of the IDT electrode 12 and a second side opposite the first side. Depending on the material selected and the application, the second layer 16 of the IDT electrode 12 can impact electrical properties of the SAW resonator 1.

The IDT electrode 12 can include any suitable IDT electrode material. For example, the IDT electrode 12 can include molybdenum (Mo), aluminum (Al), copper (Cu), Magnesium (Mg), titanium (Ti), tungsten (W), the like, or any suitable combination thereof. The IDT electrode 12 may include alloys, such as AlMgCu, AlCu, etc. A mass loading exchange rate of the first layer 14 can be greater than a mass loading exchange rate of the second layer 16. A mass loading exchange rate can be determined based on the material of the first layer 14 or the second layer 16 and mass loading effect provided by the first layer 14 or the second layer 16.

Table 1 provided below shows normalized mass loading exchange rates of aluminum (Al), molybdenum (Mo), tungsten (W), platinum (Pt), ruthenium (Ru), titanium (Ti), copper (Cu), and gold (Au) normalized by the mass loading exchange rate of molybdenum (Mo). Table 1 also shows mass densities and Young's moduli of the materials.

TABLE 1

| | Exchange rate | | Young's |
|---|---|---|---|
| | normalized | Density | modulus |
| Material | by Mo | p[kg/m3] | E[N/m\hat{ }2] |
| Al | 0.47 | 2690 | 6.773E+10 |
| Mo | 1.00 | 10220 | 3.654E+11 |
| W | 1.87 | 19300 | 3.450E+11 |
| Pt | 2.27 | 17700 | 1.520E+11 |
| Ru | 1.17 | 12410 | 4.140E+11 |
| Ti | 0.57 | 4500 | 1.161E+11 |
| Cu | 1.03 | 8930 | 1.297E+11 |
| Au | 2.68 | 19300 | 8.085E+10 |

The mass loading exchange rate of the material can generally be proportional to the mass density of the material. In some embodiments, a thickness t1 of the first layer 14 can be determined based at least in part on the normalized mass loading exchange rate shown in Table 2. In some embodiments, the thickness t1 of the first layer 14 can be determined based at least in part on the density of a material. For example, the thickness t1 of the first layer 14 can be in a range between 0.01 L and 0.055 L, 0.01 L and 0.05 L, 0.015 L and 0.055 L, 0.01 L and 0.05 L, or 0.02 L and 0.05 L multiplied by a normalized value of the first mass density normalized by a mass density of molybdenum. More specifically, the thickness t1 of the first layer 14 can be in a range between 0.01 L and 0.055 L, 0.01 L and 0.05 L, 0.015 L and 0.055 L, 0.01 L and 0.05 L, or 0.02 L and 0.05 L, multiplied by (10220/p) in which ρ is the density of the material used for the first layer 14. In some embodiments, for example, the first layer 14 can be molybdenum (Mo) and the second layer 16 can be aluminum (Al), or the first layer 14 can be tungsten (W) and the second layer 16 can be aluminum (Al).

The first layer 14 has the thickness t1 and the second layer 16 has a thickness t2. The thickness t1 of the first layer 14 and the thickness t2 of the second layer 16 can be determined based at least in part on the wavelength L of surface acoustic wave generated by the SAW device 1. The wavelength L can be, for example, in a range between 2 μm and 7 μm, 3 μm and 6 μm, 4 μm and 5.5 μm, 3 μm and 4 μm, or 5 μm and 6 μm. In some embodiments, the thickness t1 of the first layer 14 can be in a range between 0.01 L and 0.055 L, 0.01 L and 0.05 L, 0.015 L and 0.055 L, or 0.01 L and 0.05 L. In some embodiments, the thickness t2 of the second layer 16 can be in a range between 0.02 L and 0.08 L, 0.03 L and 0.08 L, 0.04 L and 0.08 L, 0.02 L and 0.06 L, 00.045 L and 0.08 L, 0.04 L and 0.07 L, 0.045 L and 0.07 L, or 0.03 L and 0.06 L. The thickness t2 of the second layer 16 can be greater than the thickness t1 of the first layer 14. For example, the thickness t2 of the second layer 16 can be in a range between 1 and 2.5 times, 1.5 and 2.5 times or between 1.8 and 2.2 times the thickness t1 of the first layer 14. In some embodiments, the second layer 16 can have a minimum thickness of about 100 nanometers, about 120 nanometers, or about 150 nanometers. Selecting the thicknesses t1, t2 of the first and second layers 14, 16 from the thickness ranges and ratios disclosed herein can be critical in providing a more reliable, more durable SAW device with a relatively high quality factor (Q) as compared to a similar SAW device with IDT layer thickness outside of these ranges.

Table 2 provided below shows example thicknesses of the first and second layers 14, 16 when the first layer 14 is a molybdenum layer and the second layer 16 is an aluminum layer for the wavelengths L of 4 micrometers (μm), 5.5 μm, and 4.5 μm. In some embodiments, the first and second layers 14, 16 can have thicknesses within 10% or within 5% of the values provided in Table 2.

TABLE 2

| L (μm) | Al (nm) | Mo (nm) | Al (L) | Mo (L) | Al/Mo ratio |
|---|---|---|---|---|---|
| 4 | 200 | 100 | 0.05 | 0.025 | 2 |
| 4 | 200 | 200 | 0.05 | 0.05 | 1 |
| 5.5 | 330 | 160 | 0.06 | 0.029 | 2.063 |
| 4.5 | 330 | 160 | 0.073 | 0.036 | 2.063 |
| 5.5 | 193 | 193 | 0.035 | 0.035 | 1 |
| 5.5 | 200 | 200 | 0.36 | 0.36 | 1 |
| 5.5 | 200 | 250 | 0.036 | 0.045 | 0.8 |
| 5.5 | 400 | 140 | 0.073 | 0.025 | 2.857 |

Table 3 provided below shows example thicknesses of the first and second layers 14, 16 when the first layer 14 is a tungsten layer and the second layer 16 is an aluminum layer for the wavelength L of 5.5 μm. In some embodiments, the first and second layers 14, 16 can have thicknesses within 10% or within 5% of the values provided in Table 3.

TABLE 3

| L (μm) | Al (nm) | W (nm) | Al (L) | W (L) | Al/W ratio |
|---|---|---|---|---|---|
| 5.5 | 180 | 80 | 0.033 | 0.015 | 2.25 |

In some embodiments, a width of the first layer 14 can be different from a width of the second layer 16. For example, the width of the first layer 14 can be greater than a width of the second layer 16. Though the illustrated IDT electrode 12 is located on a surface the piezoelectric layer 10, in some other embodiments, the IDT electrode 12 can be at least partially within the piezoelectric layer 10 or embedded in the piezoelectric layer 10.

The illustrated surface acoustic wave resonator 1 includes the functional layer 18 between the piezoelectric layer 10 and the support substrate 20. The functional layer 18 can be, for example, a single crystal layer. In some embodiments, the functional layer 18 can be a silicon oxide layer (e.g., a silicon dioxide (SiO₂) layer. In some embodiment, the functional layer 18 can function as an adhesion layer. In some embodiments, a thickness of the functional layer 18 can be the same as, generally similar to, or thinner than the thickness of the piezoelectric layer 10.

The support substrate 20 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, an aluminum oxide layer, or the like. The support substrate 20 can have a relatively high acoustic impedance. For example, the support substrate 20 can have a higher impedance than an impedance of the piezoelectric layer 10 and a higher thermal conductivity than a thermal conductivity of the piezoelectric layer 10. In some embodiments, there can be a trap rich layer that may be formed at or near a surface of the support substrate 20 facing the functional layer 18. One or more additional layers can be inserted between the functional layer 18 and the support substrate 20 to prevent or mitigate the unwanted electrical leakage on the surface of the support substrate 20. For example, one or more layers that include Poly-Si, Amorphas Si, Porous Si, SiN, and/or AlN can be disposed between the functional layer 18 and the support substrate 20. Such layers can include a trap-rich layer.

The materials, the thicknesses, and the ratio between the thicknesses of the first layer 14 and the second layer 16 of the IDT electrode 12 can significantly affect strain at a boundary between the first and second layers 14, 16 and the instant destruction power (dBm) of a SAW device. Particular combination of the materials, the thicknesses, and the ratio between the thicknesses of the first layer 14 and the second layer 16 of the IDT electrode 12 disclosed herein are critical to providing desired results, and may not be obtained through routine optimization.

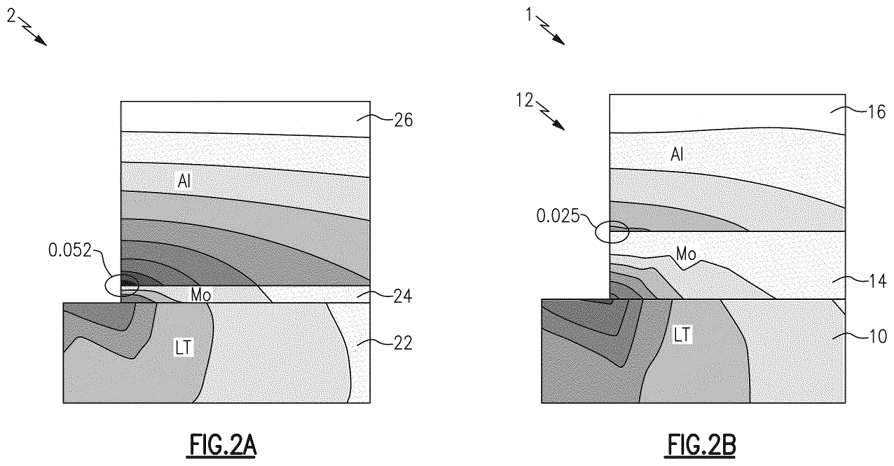

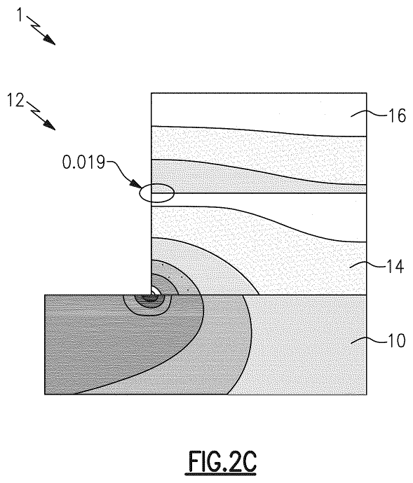

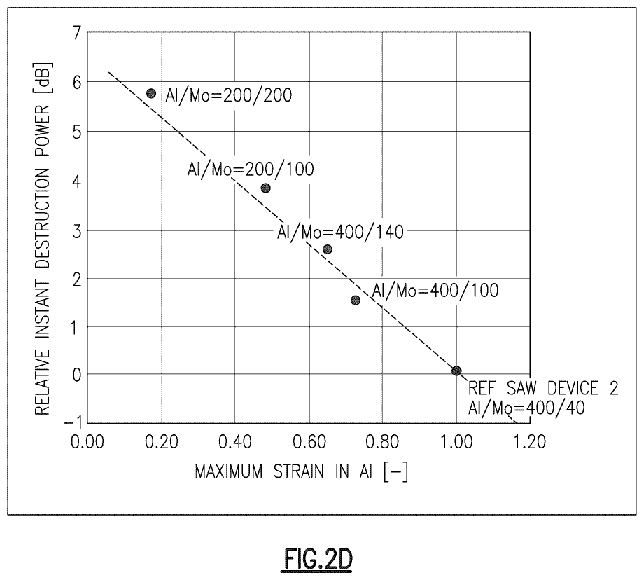

FIG. 2A shows a simulated strain distribution in a portion of a SAW device 2. Unless otherwise noted, the components of the SAW device 2 shown in FIG. 2A may be structurally and/or functionally the same as or generally similar to like components disclosed herein. The SAW device 2 shown in FIG. 2A includes a lithium tantalate piezoelectric layer 22, a molybdenum layer 24 that has a thickness of 40 nm, and an aluminum layer 26 that has a thickness of 400 nm. FIG. 2A indicates that the strain is concentrated at an edge of the aluminum layer 26 that contacts the molybdenum layer 24. At the edge of the aluminum layer 26, the strain is about 0.052. Such concentration of strain at a portion of the aluminum layer 26 can damage the aluminum layer 26 due to, for example, metal fatigue.

FIG. 2B shows a simulated strain distribution in a portion of the SAW device 1 according to an embodiment. The SAW device I used in the simulation of FIG. 2B includes a lithium tantalate layer as the piezoelectric layer 10, a molybdenum layer with a thickness of 100 nm as the first layer 14 of the IDT electrode 12, and an aluminum layer with a thickness of 200 nm as the second layer 16 of the IDT electrode 12. FIG. 2B indicates that an edge of the second layer 16 (the aluminum layer) that contacts the first layer 14 (the molybdenum layer) is about 0.025 which is significantly lower than the strain at the edge of the aluminum layer 26 in FIG. 2A. Therefore, damage to the aluminum layer can be mitigated or prevented in the SAW device 1.

FIG. 2C shows a simulated strain distribution in a portion of the SAW device 1 according to another embodiment. The SAW device I used in the simulation of FIG. 2C includes a lithium tantalate layer as the piezoelectric layer 10, a molybdenum layer with a thickness of 200 nm as the first layer 14 of the IDT electrode 12, and an aluminum layer with a thickness of 200 nm as the second layer 16 of the IDT electrode 12. The wavelength L of the wave generated by the SAW device 1 in the simulation of FIG. 2C is 4 micrometers. FIG. 2B indicates that an edge of the second layer 16 (the aluminum layer) that contacts the first layer 14 (the molybdenum layer) is about 0.019 which is significantly lower than the strain at the edge of the aluminum layer 26 in FIG. 2A. Therefore, damage to the aluminum layer can be mitigated or prevented in the SAW device 1.

FIG. 2D is a graph of four simulated results showing maximum stain in the x-axis and instant destruction power values in decibel milliwatts (dBm) in the y-axis. SAW devices similar to the SAW devices 1, 2 were used in the simulations. As compared to the SAW device 2 with the 40 nm thick aluminum layer 26, the SAW device 1 with 100 nm, 140 nm or 200 nm as the thickness t1 of the first layer 14 (e.g., the molybdenum) provides higher power durability. Simulation results of FIG. 2D indicate that a thicker first layer 14 (e.g., the molybdenum layer) and/or a thicker second layer 16 (e.g., the aluminum layer) can contribute to reducing the maximum strain in the second layer 16 and to improving the power durability. In some embodiments, the SAW device 1 can be configured to have the instant destruction power of 27 dBm or greater, 28 dBm or greater, or 29 dBm or greater. For example, when the SAW device 1 has a 200 nm thick molybdenum layer as the first layer 14 and a 200 nm thick aluminum layer as the second layer 16, the relative instant destruction power can be about 2 dB greater than when the first layer 14 is a 100 nm thick molybdenum. In some embodiments, the SAW device 1 can be configured to have the maximum strain in the second layer 16 (e.g., the aluminum layer) of 0.8 or less, 0.7 or less, or 0.6 or less.

FIG. 3A is a graph of simulated results showing an aluminum layer thickness in the x-axis and the strain in the y-axis. FIG. 3B is a graph of simulated results showing an aluminum layer thickness in the x-axis and the instant destruction power values in decibel milliwatts (dBm) in the y-axis. SAW devices similar to the SAW devices 1, 2 were used in the simulations. The simulation results of FIG. 3A indicate that the strain can be reduced when the first layer 14 (e.g., the molybdenum layer) is thicker and when the second layer 16 (e.g., the aluminum layer) is thinner. The simulation results of FIG. 3B indicate that the instant destruction power increases when the first layer 14 (e.g., the molybdenum layer) is thicker and when the second layer 16 (e.g., the aluminum layer) is thinner. The simulation results of FIGS. 3A and 3B indicate that the first thickness t1 of 0.08 L or less may be preferred in certain applications.

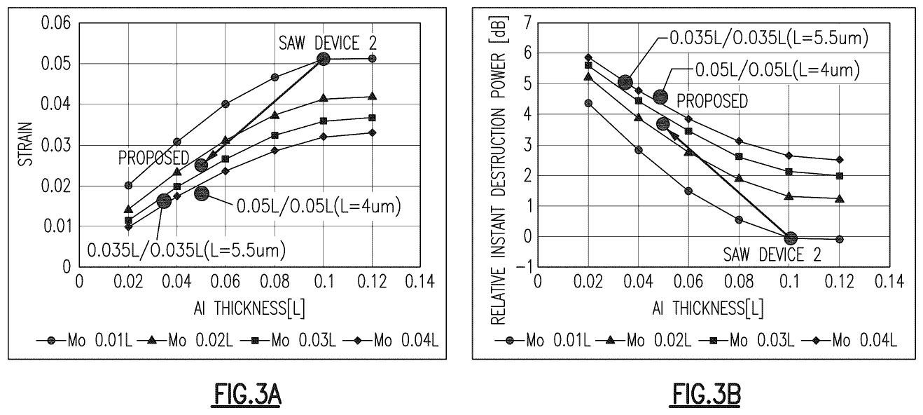

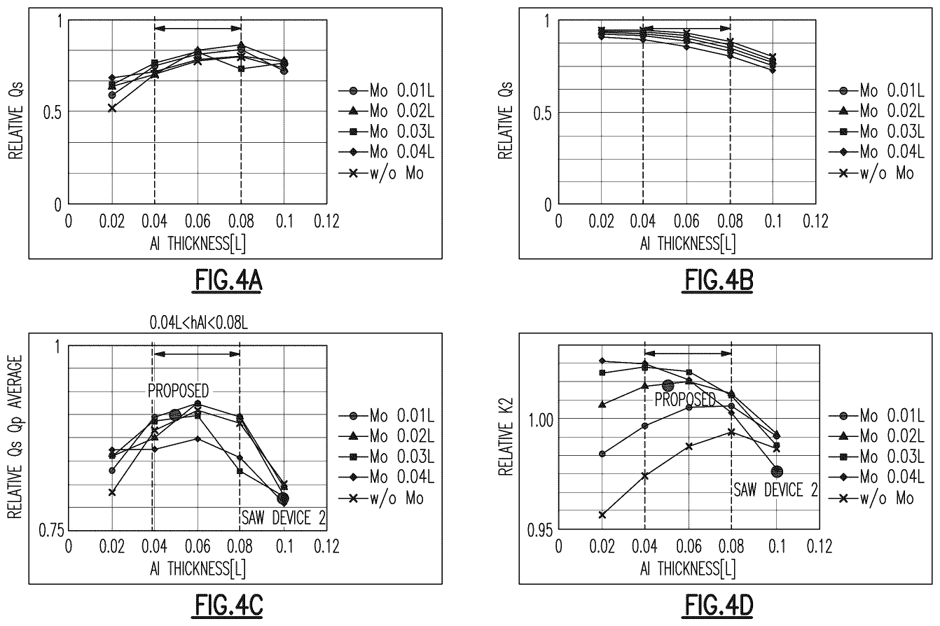

There are aspects other than the power durability and the device reliability, such as the quality factor (Q) and/or the effective electromechanical coupling coefficient (k2), that are significant in a SAW device. Selection of the first thickness t1 of the first layer 14 and the second thickness t2 of the second layer 16 based solely on the power durability and device reliability points of view may not provide a SAW device that can provide a relatively high Q and a desired k2. FIGS. 4A-4D are graphs showing quality factor (Q) and coupling coefficient (k2) of the SAW device 1 at different thicknesses of the first layer 14 (e.g., the molybdenum layer) and the second layer 16 (e.g., the aluminum layer) of the IDT electrode 12.

FIG. 4A indicates that a relatively high series quality factor Qs can be provided when the thickness t2 of the second layer 16 (e.g., the aluminum layer) is in a range between about 0.04 L and 0.08 L, and the Qs can degrade when the thickness t2 is outside of this range. FIG. 4A also indicates that the thickness t1 of the first layer 14 does not significantly affect the Qs. FIG. 4B indicates that when the thickness t2 of the second layer 16 (e.g., the aluminum layer) is in a range between about 0.04 L and 0.08 L, a relatively high parallel quality factor Qp can be provided, but the Qp can decrease as the first thickness t1 and/or the second thickness t2 increase. FIG. 4C again indicates that in terms of the Q values (e.g., Qs and Qp), the thickness t2 in a range between about 0.04 L and 0.08 L can be preferred. FIG. 4C also indicates that the thickness t1 in a range between about 0.01 L and 0.04 L can be preferred, and the thickness t1 in a range between about 0.01 L and 0.03 L can be more preferred. FIG. 4D indicates that the thickness t2 of the second layer 16 (e.g., the aluminum layer) in a range between about 0.04 L and 0.08 L can provide a sufficiently large effective electromechanical coupling coefficient (k2).

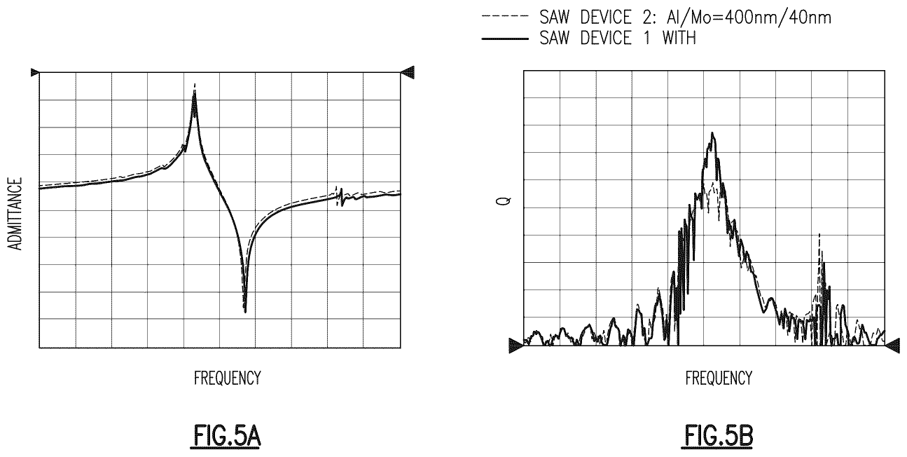

FIGS. 5A and 5B show simulated admittance and Q of the SAW device 1 with a 100 nm molybdenum layer as the first layer 14 and a 200 nm aluminum layer as the second layer 16 and the SAW device 2 of FIG. 2A. FIGS. 5A and 5B indicate that the SAW device 1 provides a similar resonant frequency and reflection coefficient as the SAW device 2 while improving the Q.

Although the molybdenum layer and the aluminum layer are used as examples of the first layer 14 and the second layer 16 of the IDT electrode 12, any suitable principles and advantages disclosed herein can be implemented with other materials. Also, any suitable principles and advantages disclosed herein can be implemented with an IDT electrode that includes more than three layers. For example, there may be an additional layer under the first layer 14, between the first layer 14 and the second layer 16, or over the second layer 16. The additional layer may include, for example, a buffer layer, a seed layer, or an adhesion layer.

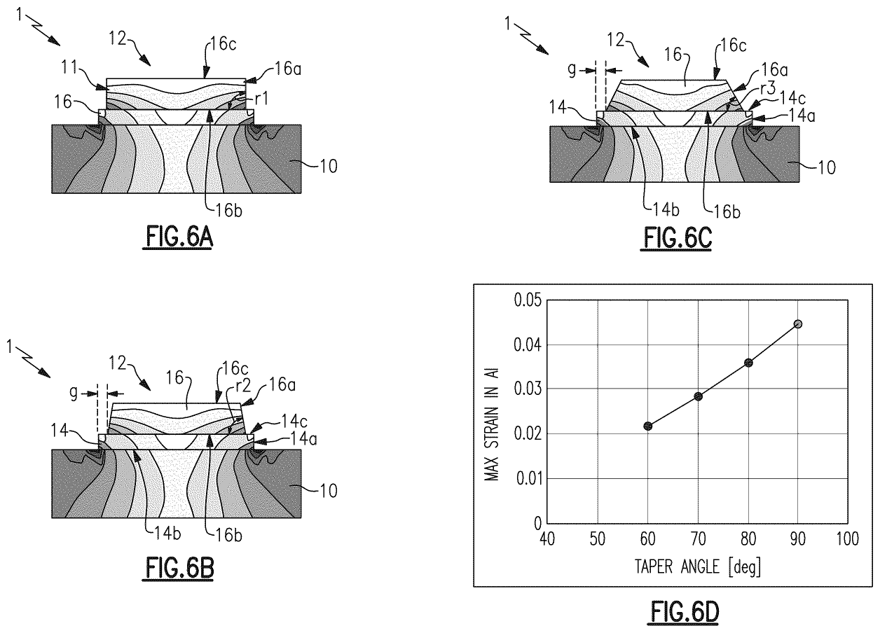

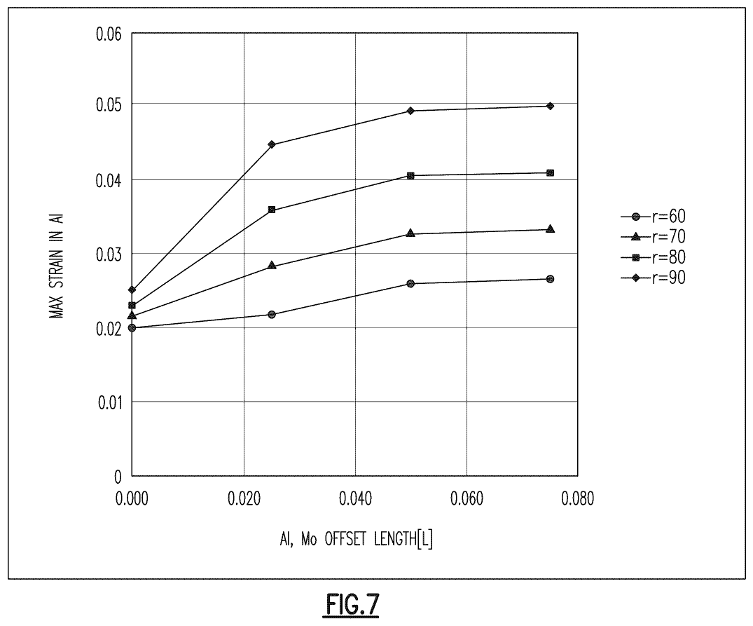

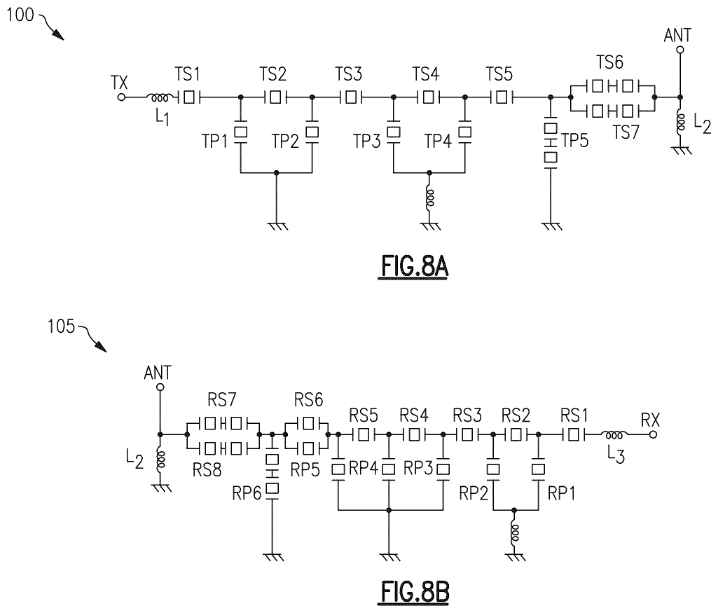

The strain in the second layer 16 can be further minimized by shaping the second layer 16 to have a sidewall with a tapered angle of less than 90 degrees, or by providing a width difference between the widths of the first and second layers 14, 16 of the IDT electrode 12. Such strain reducing structures are described with respect to FIGS. 6A-7.

FIGS. 6A-6C are schematic cross-sectional side views of the SAW device 1 showing simulated strain distributions in the SAW device 1 with different sidewall angles of the second layer 16 (e.g., the aluminum layer). In the simulation of FIG. 6A, an angle r1 between a sidewall 16a and a bottom side 16b of the second layer 16 is set to 90 degrees. The bottom side 16b can be in contact with the first layer 14 in some embodiments. In the simulation of FIG. 6B, an angle r2 between the sidewall 16a and the bottom side 16b of the second layer 16 is set to less than 90 degrees. In the simulation of FIG. 6B, an angle r3 between the sidewall 16a and the bottom side 16b of the second layer 16 is set to less than r2. FIG. 6D is a graph showing simulated maximum strain values in the second layer 16 (e.g., the aluminum layer) at different sidewall angles. FIGS. 6A-6D indicate that when the angle between the sidewall 16a and the bottom side 16b of the second layer 16 is smaller, the maximum strain in the second layer 16 can be reduced.

In some embodiments, an angle between the sidewall 16a and the bottom side 16b can be smaller than 90 degrees such that a top side 16c of the second layer 16 has a width that is less than a width of the bottom side 16b. For example, the angle between the sidewall 16a and the bottom side 16b can be in a range between 45 degrees and 95 degrees, 50 degrees and 90 degrees, or 60 degrees and 80 degrees. The first layer 14 has a sidewall 14a that extends between a bottom side 14b and a top side 14c. In some embodiments, the first layer 14 may also have an angle less than 90 degrees between the sidewall 14a and the bottom side 14b.

As shown in FIGS. 6A-6C, there can be a width difference between the widths of the first layer 14 and the second layer 16 of the IDT electrode 12. In some embodiments, the top side 14c of the first layer 14 can have a width that is greater than the bottom side 16b of the second layer 16 such that the sidewall 16a is offset by a gap g from the sidewall 14a at the top side 14c of the first layer 14. A dimension of the gap g can be referred to as an offset length.

FIG. 7 is a graph showing simulated maximum strain values in the second layer 16 (e.g., the aluminum layer) at different sidewall angles and offset lengths. FIG. 7 indicates that when there is the gap g between the sidewalls 14a, 16a, the maximum strain in the second layer 16 can be reduced. In some embodiments, the offset length of the gap g can be in a range between 0.01 L and 0.08 L, 0.01 L and 0.06 L, 0.02 L and 0.06 L, or 0.02 L and 0.05 L.

A SAW device (e.g., an MPS SAW resonator) including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS SAW resonators disclosed herein. FR1 can be from 410 MHZ to 7.125 GHz, for example, as specified in a current 5G NR specification. In 5G applications, the thermal dissipation of the MPS SAW resonators disclosed herein can be advantageous. For example, such thermal dissipation can be desirable in 5G applications with a higher time-division duplexing (TDD) duty cycle compared to fourth generation (4G) Long Term Evolution (LTE). One or more MPS SAW resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

FIG. 8A is a schematic diagram of an example transmit filter 100 that includes surface acoustic wave resonators according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. For instance, one or more of the SAW resonators of the transmit filter 100 can be a surface acoustic wave device disclosed herein. Alternatively or additionally, one or more of the SAW resonators of the transmit filter 100 can be any surface acoustic wave resonator disclosed herein. Any suitable number of series SAW resonators and shunt SAW resonators can be included in a transmit filter 100.

FIG. 8B is a schematic diagram of a receive filter 105 that includes surface acoustic wave resonators according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. For instance, one or more of the SAW resonators of the receive filter 105 can be a surface acoustic wave device disclosed herein. Alternatively or additionally, one or more of the SAW resonators of the receive filter 105 can be any surface acoustic wave resonator disclosed herein. Any suitable number of series SAW resonators and shunt SAW resonators can be included in a receive filter 105.

Although FIGS. 8A and 8B illustrate example ladder filter topologies, any suitable filter topology can include a SAW resonator in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

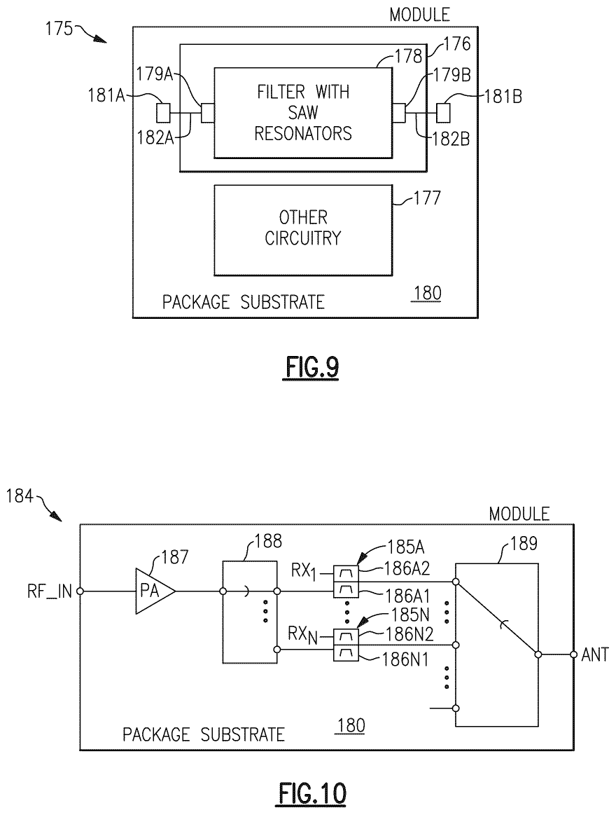

FIG. 9 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 9 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 9. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

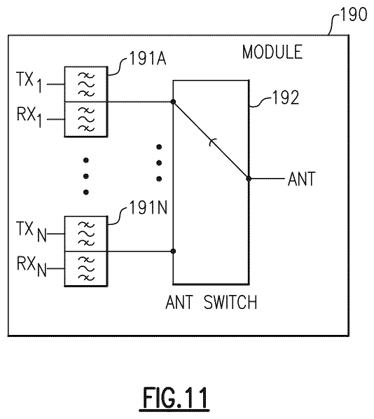

FIG. 10 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 11 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

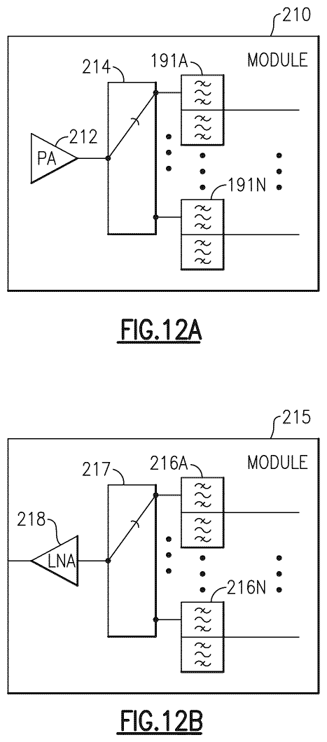

FIG. 12A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 12B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

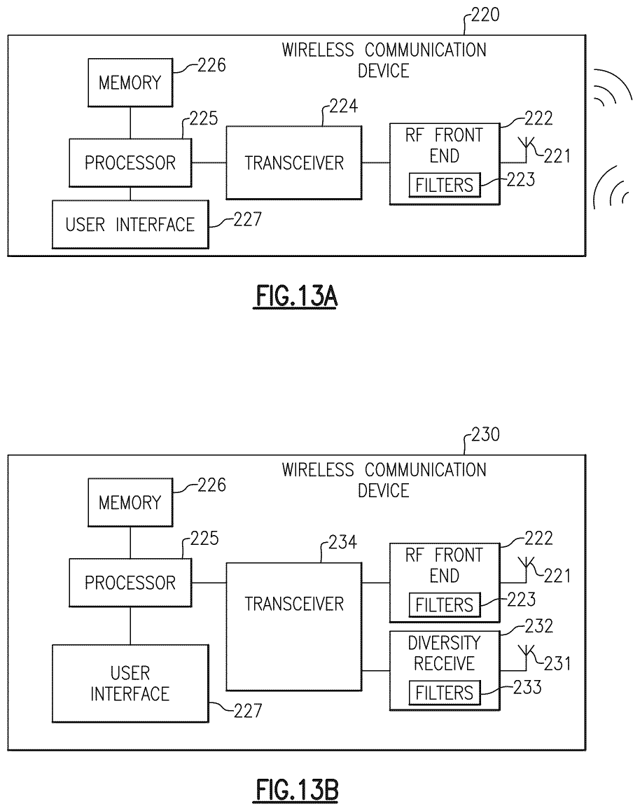

FIG. 13A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 13B is a schematic diagram of a wireless communication device 230 that includes filters 223 in a radio frequency front end 222 and a second filter 233 in a diversity receive module 232. The wireless communication device 230 is like the wireless communication device 200 of FIG. 13A, except that the wireless communication device 230 also includes diversity receive features. As illustrated in FIG. 13B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHZ, such as in a frequency range from about 450 MHz to 8.5 GHZ. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A multi-layer piezoelectric substrate surface acoustic wave device configured to generate a wave having a wavelength of L, the multi-layer piezoelectric substrate surface acoustic wave device comprising:
a substrate;
a piezoelectric layer over the substrate; and
a multi-layer interdigital transducer electrode in electrical communication with the piezoelectric layer, the multi-layer interdigital transducer electrode including a first layer having molybdenum and a second layer having aluminum, a first thickness of the first layer being in a range between 0.02 L and 0.05 L, a second thickness of the second layer being in a range between 1 and 2.5 times the first thickness.

2. The multi-layer piezoelectric substrate surface acoustic wave device of claim 1 wherein the second thickness is 100 nanometers or greater.

3. The multi-layer piezoelectric substrate surface acoustic wave device of claim 1 wherein the second thickness is 0.08 L or less.

4. The multi-layer piezoelectric substrate surface acoustic wave device of claim 1 wherein the piezoelectric layer includes lithium tantalate or lithium niobate.

5. The multi-layer piezoelectric substrate surface acoustic wave device of claim 1 wherein the wavelength is in a range between 3 micrometers to 6 micrometers.

6. The multi-layer piezoelectric substrate surface acoustic wave device of claim 1 wherein the second thickness of the second layer is in a range between 1.8 times and 2.2 times the first thickness.

7. The multi-layer piezoelectric substrate surface acoustic wave device of claim 1 further comprising a functional layer between the substrate and the piezoelectric layer.

8. The multi-layer piezoelectric substrate surface acoustic wave device of claim 1 wherein the second layer has a sidewall that extends between a bottom side and a top side of the second layer, an angle between the sidewall and the bottom side is in a range between 45 degrees and 95 degrees.

9. The multi-layer piezoelectric substrate surface acoustic wave device of claim 8 wherein a first width of the first layer is greater than a second width of the second layer.

10. The multi-layer piezoelectric substrate surface acoustic wave device of claim 9 wherein the sidewall of the second layer is offset from a sidewall of the first layer by an offset length in a range between 0.01 L and 0.08 L.

11. The multi-layer piezoelectric substrate surface acoustic wave device of claim 1 wherein the first layer is at least partially positioned in the piezoelectric layer.

12. A multi-layer piezoelectric substrate surface acoustic wave device configured to generate a wave having a wavelength of L, the multi-layer piezoelectric substrate surface acoustic wave device comprising:
a substrate;
a piezoelectric layer over the substrate; and
a multi-layer interdigital transducer electrode in electrical communication with the piezoelectric layer, the multi-layer interdigital transducer electrode including a first layer and a second layer over the first layer, the second layer having aluminum, a first thickness of the first layer being in a range between 0.02 L and 0.05 L, a second thickness of the second layer being in a range between 1 and 2.5 times the first thickness, the second thickness being 100 nanometers or greater and 0.08 L or less.

13. The multi-layer piezoelectric substrate surface acoustic wave device of claim 12 wherein the piezoelectric layer includes lithium tantalate or lithium niobate.

14. The multi-layer piezoelectric substrate surface acoustic wave device of claim 12 wherein the wavelength is in a range between 3 micrometers to 6 micrometers.

15. The multi-layer piezoelectric substrate surface acoustic wave device of claim 12 wherein the second thickness of the second layer is in a range between 1.8 times and 2.2 times the first thickness.

16. The multi-layer piezoelectric substrate surface acoustic wave device of claim 12 further comprising a functional layer between the substrate and the piezoelectric layer.

17. The multi-layer piezoelectric substrate surface acoustic wave device of claim 12 wherein the second layer has a sidewall that extends between a bottom side and a top side of the second layer, an angle between the sidewall and the bottom side is in a range between 45 degrees and 95 degrees.

18. The multi-layer piezoelectric substrate surface acoustic wave device of claim 17 wherein a first width of the first layer is greater than a second width of the second layer.

19. The multi-layer piezoelectric substrate surface acoustic wave device of claim 18 wherein the sidewall of the second layer is offset from a sidewall of the first layer by an offset length in a range between 0.01 L and 0.08 L.

20. An acoustic wave filter comprising:
a multi-layer piezoelectric substrate surface acoustic wave device configured to filter a wave having a wavelength of L, the multi-layer piezoelectric substrate surface acoustic wave device including a multi-layer interdigital transducer electrode formed with a piezoelectric layer, the multi-layer interdigital transducer electrode including a first layer having molybdenum and a second layer having aluminum, a first thickness of the first layer being in a range between 0.02 L and 0.05 L, a second thickness of the second layer being in a range between 1 and 2.5 times the first thickness; and
a plurality of other acoustic wave devices, the multi-layer piezoelectric substrate surface acoustic wave device and the plurality of other acoustic wave devices together arranged to filter a radio frequency signal.
